(19) United States
(12) Patent Application Publication
(10) Pub. No.: US 2005/0074905 A1
(43) Pub. Date: Apr. 7, 2005

(54) Inductors in semiconductor devices and methods of manufacturing the same

(76) Inventor: Yong-Geun Lee, Eumsung-kun (KR)

Correspondence Address: GROSSMAN & FLIGHT LLC, Suite 4220, 20 North Wacker Drive, Chicago, IL, 60606-6357, US

(21) Appl. No.: 10/956,612

(22) Filed: Sep. 30, 2004

(30) Foreign Application Priority Data
Oct. 1, 2003 (KR) 10-2003-0068496

(51) Int. Cl. H01L 21/00

(52) U.S. Cl. 438/3

(57) ABSTRACT

Inductors in semiconductor devices and methods of manufacturing the same are disclosed. A disclosed inductor includes: a semiconductor substrate; a first dielectric layer on the substrate; a first spiral shaped, metal wire on the first dielectric layer; and a second dielectric layer on the first metal wire and the first dielectric layer. The second dielectric layer has a spiral shaped contact hole exposing the first metal wire. The inductor also includes a second metal wire on the second dielectric layer and electrically connected to the first metal wire through the contact hole. A boundary line of the second metal wire is substantially aligned with a boundary line of the first metal wire.

### FIELD OF THE DISCLOSURE

The present disclosure relates generally to semiconductor devices, and more particularly to inductors in semiconductor devices and methods of manufacturing the same.

### BACKGROUND

An inductor is a common element in high frequency transceiver circuits. Inductors are necessarily used in radio frequency (RF) devices and analog devices that are developing with the expansion of the wireless communication market.

An inductor formed on a GaAs or Si substrate as a spiral metal wire in an integrated circuit is described in U.S. Pat. No. 6,395,637.

Unfortunately, the most important characteristic of the inductor, namely, the quality factor Q, is adversely affected by undesired characteristics such as parasitic resistance and capacitance. When the Q factor deteriorates the self-resonant frequency (fωo) becomes lower. As a result of this variance in the self-resonant frequency, it is very difficult to directly apply the inductor in a high frequency integrated circuit.

To overcome these problems, a low resistance metal such as Au has been used as a metal wire material, and the metal wire has been thickly formed to reduce parasitic resistance and capacitance. Furthermore, multiple layer metal wires (e.g., wires with more than three layers) have also been used to reduce parasitic resistance and capacitance as described in U.S. Pat. No. 5,497,337. However, metal wires having more than three layers require complicated fabrication processes and, thus, result in very expensive fabrication costs.

However, when using Au as the metal wire material, the fabrication cost is very expensive due to the high cost of Au. Additionally, a metal wire process using Au is difficult to apply to a monolithic high frequency integrated circuit on silicon while forming a thick metal layer to reduce parasitic resistance.

If a thick dielectric layer is applied to a passive element such as an inductor, parasitic capacitance is reduced.

### BRIEF DESCRIPTION OF THE DRAWINGS

FIG. 1 is a plan view showing an example inductor constructed in accordance with the teachings of the present invention.

FIG. 2 is a partial cross-sectional view of the inductor taken along line II-Il′ of FIG. 1.

FIG. 3A to FIG. 3F are cross-sectional views illustrating various times in an example method of manufacturing an inductor for a semiconductor device performed in accordance with the teachings of the present invention.

FIGS. 4A to 4C are cross-sectional views illustrating various times in another example method of manufacturing an inductor for a semiconductor device performed in accordance with the teachings of the present invention.

### DETAILED DESCRIPTION

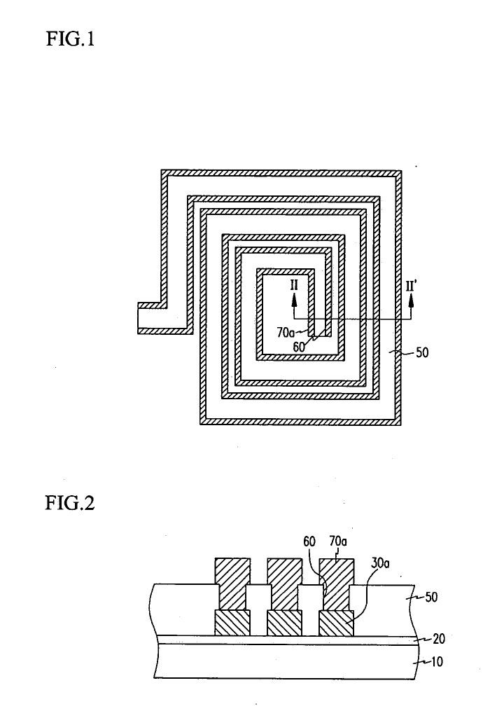

An example inductor in an example semiconductor device is shown in FIG. 1 and FIG. 2. Referring to FIG. 1 and FIG. 2, a first dielectric layer 20 is formed on a semiconductor substrate 10 on which a lower structure (not shown) of an active device such as a CMOS device is formed. In the illustrated example, the semiconductor substrate 10 is a Si substrate, and the first dielectric layer 20 is an oxide such as a TEOS.

A first metal wire 30a of a spiral shape is formed on the first dielectric layer 20. The first metal wire 30a is electrically connected to the active device on the substrate 10 through a contact hole (not shown) formed in the first dielectric layer 20. A second dielectric layer 50 is relatively thickly formed on the first metal wire 30a and the first dielectric layer 20 so as to fill the space between the first metal wires. The second dielectric layer has a contact hole 60 exposing a portion of the first metal wire 30a. The contact hole 60 is formed in a spiral shape along the first metal wire 30a and has a narrower width than the first metal wire 30a. In the illustrated example, the second dielectric layer 50 is a SiO₂/SOG/SiO₂ layer.

A second metal wire 70a is formed on the second dielectric layer 50 so as to be electrically connected to the first metal wire 30a through the contact hole 60. The second metal wire 70a is formed of an Al layer and is overlapped with the first metal wire 30a so that its boundary line is aligned with that of the first metal wire 30a.

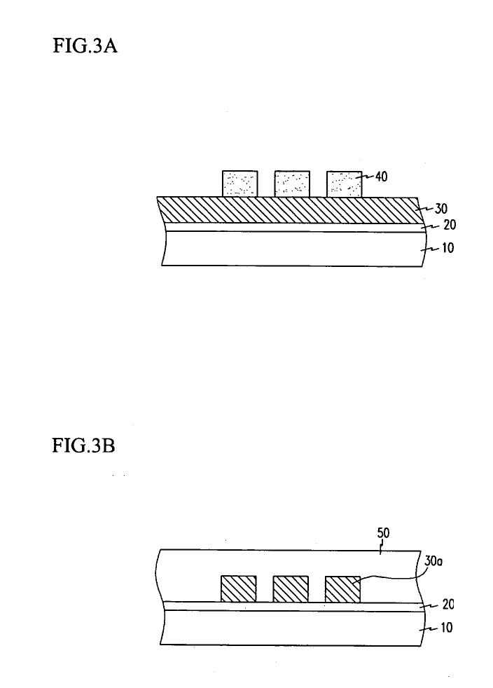

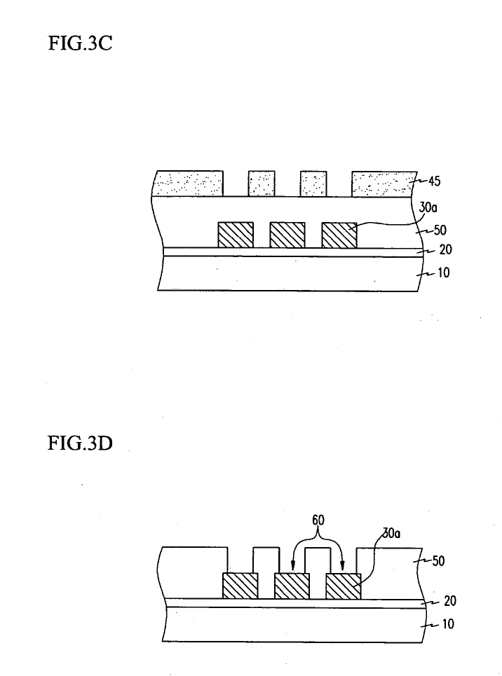

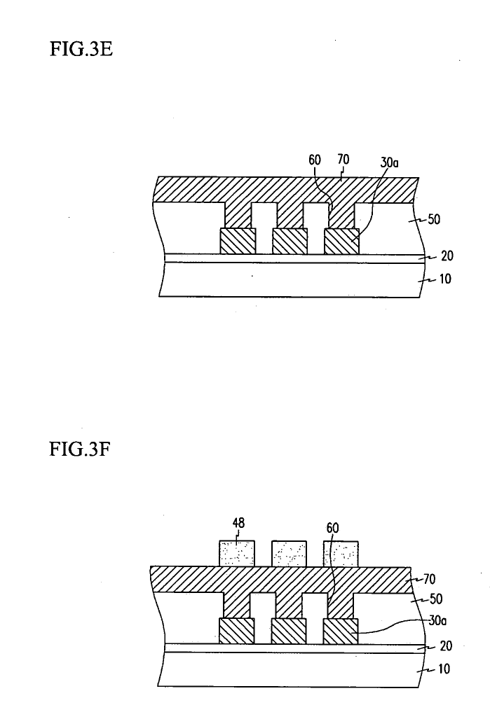

An example method of manufacturing the inductor shown in FIGS. 1 and 2 will now be described with reference to FIGS. 3A-3F and FIG. 2. Referring to FIG. 3A, an active device (e.g., a portion of a CMOS structure (not shown)) is formed in a semiconductor substrate 10. In the illustrated example, the semiconductor substrate 10 is a silicon substrate having a high resistance of about 100˜2000 Ω·cm. A first dielectric layer 20 having one or more contact hole(s) (not shown) exposing portion(s) of the active device (e.g., portions of a CMOS structure) is then formed on the entire surface of the substrate 10. In the illustrated example, the first dielectric layer 20 is formed of an oxide such as a TEOS. The first dielectric layer 20 isolates the active device(s).

Thereafter, a first metal layer 30 is formed on the first dielectric layer 20. Then, a first photoresist layer is coated on the first metal layer 30. The photoresist layer is then exposed and developed to form a first photoresist pattern 40 having a spiral shape.

Referring to FIG. 3B, the first metal layer 30 is etched using the first photoresist pattern 40 (as shown in FIG. 3A) as an etch mask to form a first metal wire 30a having the spiral shape of the mask on the first dielectric layer 20. The first metal wire 30a is electrically connected to one or more active device(s) in the substrate 10 through the contact hole(s) of the first dielectric layer 20.

Next, the first photoresist pattern 40 is removed by a well-known conventional method. A second, relatively thick, dielectric layer 50 is then formed so as to fill the spaces between the first metal wire 30a. In the illustrated example, the second dielectric layer 50 is a SiO₂/SOG/SiO₂ layer.

Referring to FIG. 3C, a second photoresist layer is coated on the second dielectric layer 50. The second photoresist layer is then exposed and developed to form a second photoresist pattern 45 exposing portion(s) of the second dielectric layer 50 over the first metal wire 30a. The width(s) of the area(s) of the second dielectric layer 50 exposed by the second photoresist pattern 45 are narrower than the width(s) of the corresponding portion(s) of the first metal wire 30a,

Referring to FIG. 3D, the exposed portion(s) of the second dielectric layer 50 are etched using the second photoresist pattern 45 (as shown in FIG. 3C) as an etch mask, to form contact hole(s) 60 exposing the portion(s) of the first metal wire 30a in the second dielectric layer 50. The second photoresist pattern 45 is then removed by a well-known conventional method.

Referring to FIG. 3E, a second metal layer 70 is formed on the second dielectric layer 50 so as to fill the contact hole(s) 60. In the illustrated example, the second metal layer 70 is formed by coating and reflowing an Al layer. The second metal layer 70 is thicker than the depth of the contact hole(s) 60. Therefore, the contact hole 60 is filled with the second metal layer 70, and the second metal layer 70 has a substantially uniform thickness.

A barrier layer (not shown) may be formed by depositing a conductive material such as a TIN on the second dielectric layer 50 before forming the second metal layer 70.

Referring to FIG. 3F, a third photoresist layer is coated on the second metal layer 70. The third photoresist layer is exposed and developed to form a third photoresist pattern 48 having a spiral shape which is the same as the spiral shape of the first photoresist pattern 40 (see FIG. 3A). The second metal layer 70 is then etched using the third photoresist pattern 48 as an etch mask to form a second, spiral shaped metal wire 70a which is electrically connected to the first metal wire 30a through the contact hole(s) 60 as shown in FIG. 2. As shown in FIG. 2, the second metal wire 70a overlaps with the first metal wire 30a so that the boundary line of the second metal wire 70a is substantially aligned with the boundary line of the first metal wire 30a. Thereafter, the third photoresist pattern 48 is removed by a well-known conventional method.

When etching the second metal layer 70 in the above example, the third photoresist pattern 48 is used as the etch mask. However, an additional dielectric layer pattern can alternatively be used as the etch mask to prevent the second metal wire 70a from corroding.

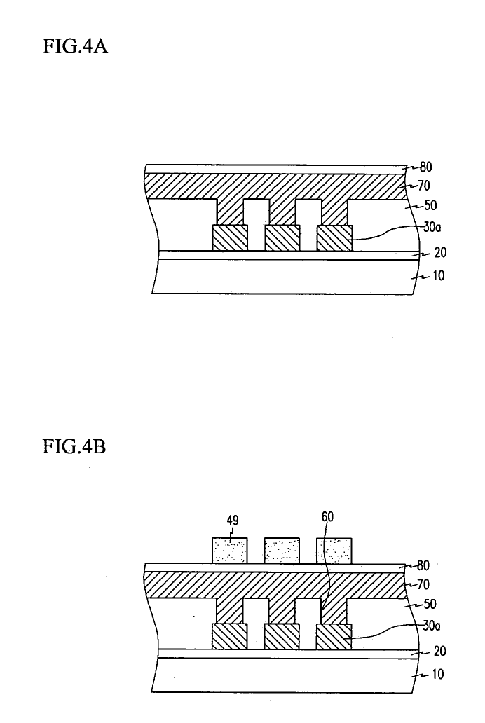

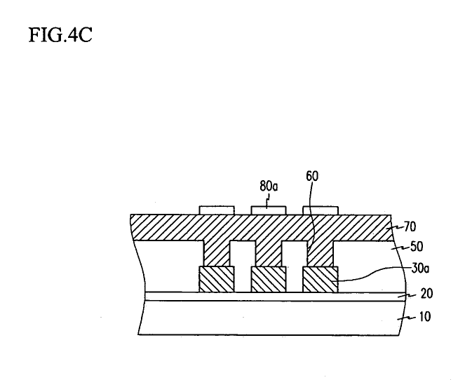

Another example method of manufacturing an inductor for a semiconductor device using the above dielectric layer pattern will now be described with reference to FIGS. 4A to 4C and FIG. 2. Referring to FIG. 4A, the first dielectric layer 20, the first metal wire 30a, the second dielectric layer 50 having the contact hole(s) 60 and the second metal layer 70 are formed on the semiconductor substrate 10 by the same process as the first example method (see FIG. 3A to 3E and the accompanying description).

Next, a third dielectric layer 80 is formed on the second metal layer 70. The third dielectric layer 80 is formed of a material having high etch selectivity (e.g., 10:1) relative to the second metal layer 70. The third dielectric layer 80 is preferably a silicon oxide layer, a silicon nitride layer or a composition of a silicon oxide layer and a silicon nitride layer. The thickness of the third dielectric layer 80 may vary as the thickness of the second metal layer 70.

Referring to FIG. 4B, a fourth photoresist layer is coated on the third dielectric layer 80. The fourth photoresist layer is exposed and developed to form a fourth photoresist pattern 49 which is the same as the first photoresist pattern 40 shown in FIG. 3A.

Referring to FIG. 4C, the third dielectric layer 80 is etched using the fourth photoresist pattern 49 shown in FIG. 4B as an etch mask to form a dielectric layer pattern 80a having a spiral shape. The fourth photoresist pattern 49 is then removed by a well-known conventional method.

Thereafter, the second metal layer 70 is etched by dry etching using the dielectric pattern 80a as an etch mask to form the second metal wire 70a. The second metal wire 70a is electrically connected to the first metal wire 30a through the contact hole(s) 60 as shown in FIG. 2A. The second metal wire 70a overlaps with the first metal wire 30a so that its boundary line is substantially aligned with the boundary line of the first metal wire 30a.

In the examples described above, the spiral shaped metal wires forming the inductor are connected to each other through the contact hole 60 of the spiral shape. As a result, parasitic capacitance and resistance are effectively reduced, thereby improving the performance of the inductor.

Consequently, there is no need for the metal wire to be formed with multiple metal wires of more than three layers, or for the metal wire to be formed with Au. Accordingly, the high cost and complicated processes associated with the prior art are not required to manufacture the inductor, and the inductor is easy to apply to an integrated circuit.

From the foregoing, persons of ordinary skill in the art will appreciate that an inductor has been provided for use in a semiconductor device wherein the inductor is capable of obtaining high performance by effectively reducing parasitic resistance and parasitic capacitance.

A disclosed inductor includes: a semiconductor substrate; a first dielectric layer formed on the substrate; a first spiral shaped, metal wire formed on the first dielectric layer; a second dielectric layer formed on the first metal wire and the first dielectric layer and having a contact hole exposing a portion of the first metal wire, the contact hole having a spiral shape and being located along the first metal wire; and a second metal wire formed on the second dielectric layer and electrically connected to the first metal wire through the contact hole, wherein the boundary line of the second metal wire is substantially aligned with the boundary line of the first metal wire.

Furthermore, a disclosed method of manufacturing an inductor comprises: sequentially forming a first dielectric layer and a first metal layer on a semiconductor substrate; forming a first spiral shaped, metal wire on the first dielectric layer by etching the first metal layer; forming a second dielectric layer on the first metal wire and the first dielectric layer so as to fill between the first metal wire; etching the second dielectric layer over the first metal wire to form a spiral shaped contact hole to expose a portion of the first metal wire; forming a second metal layer on the second dielectric layer so as to fill the contact hole; and forming a second spiral shaped, metal wire so that its boundary line is substantially aligned with the boundary line of the first metal wire by etching the second metal layer.

Forming the second metal wire includes: forming a mask pattern having a spiral shape with a boundary line that is substantially aligned with the boundary line of the first metal wire on the second metal layer; etching the second metal layer using the mask pattern; and removing the mask pattern.

In the illustrated example, the mask pattern is a photoresist pattern or a dielectric layer pattern. The dielectric pattern is fabricated by forming and selectively etching a third dielectric layer on the second metal layer. In the illustrated example, the ratio of the etch selectivity of the material forming the third dielectric layer relative to the etch selectivity of the second metal layer is about 10:1.

It is noted that this patent claims priority from Korean Patent Application Serial Number 10-2003-0068496, which was filed on Oct. 1, 2003, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. An inductor comprising:
a semiconductor substrate;
a first dielectric layer on the substrate;
a first spiral shaped, metal wire on the first dielectric layer;
a second dielectric layer on the first metal wire and the first dielectric layer, the second dielectric layer having a spiral shaped contact hole exposing the first metal wire; and
a second metal wire on the second dielectric layer and electrically connected to the first metal wire through the contact hole, wherein a boundary line of the second metal wire is substantially aligned with a boundary line of the first metal wire.

2. An inductor as defined in claim 1, wherein a width of the contact hole is narrower than a width of the first metal wire.

3. A method of manufacturing an inductor comprising:
sequentially forming a first dielectric layer and a first metal layer on a semiconductor substrate;
etching the first metal layer to form a first spiral shaped, metal wire on the first dielectric layer;
forming a second dielectric layer on the first metal wire and the first dielectric layer;
etching the second dielectric layer to form a spiral shaped contact hole over the first metal wire;
forming a second metal layer on the second dielectric layer, the second metal layer filling the contact hole; and
etching the second metal layer to form a second spiral shaped, metal wire having a boundary line in substantial alignment with a boundary line of the first metal wire.

4. A method as defined in claim 3, wherein etching the second metal wire comprises:
forming a spiral shaped mask pattern on the second metal layer, the spiral shaped mask pattern having a boundary line in substantial alignment with the boundary line of the first metal wire;
etching the second metal layer using the mask pattern; and
removing the mask pattern.

5. A method as defined in claim 4, wherein the mask pattern is a photoresist pattern.

6. A method as defined in claim 4, wherein the mask pattern is a dielectric layer pattern that is formed by selectively etching a third dielectric layer formed on the second metal layer.

7. A method as defined in claim 6, wherein a ratio of an etch selectivity of a material forming the third dielectric layer to an etch selectivity of the second metal layer is about 10:1.

8. A method as defined in claim 7, wherein the third dielectric layer is formed of a silicon oxide layer, a silicon nitride layer or a composition layer of a silicon oxide layer and a silicon nitride layer.

9. A method as defined in claim 3, wherein the second dielectric layer fills a space between at least two adjacent portions of the first metal wire.
